(19) United States
(12) Patent Application Publication
(10) Pub. No.: US 2007/0257699 A1
(43) Pub. Date: Nov. 8, 2007

(54) Multi-memory module circuit topology

(76) Inventors: Moises Cases, Austin, TX (US); Daniel N. De Araujo, Cedar Park, TX (US); Erdem Matoglu, Austin, TX (US); Pravin Patel, Cary, NC (US); Nam H. Pham, Round Rock, TX (US)

Correspondence Address: IBM (RPS-BLF);c/o BIGGERS & OHANIAN, LLP, P.O. BOX 1469, AUSTIN, TX, 78767-1469, US

(21) Appl. No.: 11/407,814

(22) Filed: Apr. 20, 2006

(51) Int. Cl. H03K 17/16

(52) U.S. Cl. 326/30

(57) ABSTRACT

A multi-memory module circuit topology is disclosed that includes a memory controller, a plurality of memory modules connected to the memory controller through a memory bus, and a resonator connected to the plurality of memory modules in a starburst topology. A method for reducing impedance discontinuities in a multi-memory module circuit is disclosed that includes providing a plurality of memory modules connected to a memory controller through a memory bus, selecting a starburst topology, and connecting a resonator to the plurality of memory module in dependence upon the selected starburst topology. An additional method for reducing impedance discontinuities in a multi-memory module circuit is disclosed that includes providing by a resonator a predetermined discontinuity reducing impedance at a predetermined location in the multi-memory module circuit between at least two memory modules, the multi-memory module circuit having a plurality of components of logically arranged around the predetermined location.

### BACKGROUND OF THE INVENTION

1. Field of the Invention

The field of the invention is multi-memory module circuit topologies.

2. Description Of Related Art

The development of the EDVAC computer system of 1948 is often cited as the beginning of the computer era. Since that time, computer systems have evolved into extremely complicated devices. Today's computers are much more sophisticated than early systems such as the EDVAC. Computer systems typically include a combination of hardware and software components, application programs, operating systems, processors, buses, memory, input/output devices, and so on. Advances in semiconductor processing and computer architecture have served to push the performance of the computer higher and higher and have resulted in computer systems today that are much more powerful than just a few years ago.

Throughout the advancement of semiconductor processing and computer architecture, advancements in computer memory subsystems have played an important role in creating more powerful computers. To maintain the steady overall increase in computer performance, increases in the speed of computer memory subsystems have complimented increases in speed of computer processors. Over the last several years, increases in the performance of computer memory subsystems have increased by several orders of magnitude. Just a few years ago, the operational speed of computer memory subsystems was measured in kilohertz. Today, the operational speed of computer memory subsystems is measured in megahertz.

Currently, the Joint Electron Device Engineering Council (‘JEDEC’) serves an important source of computer memory subsystem performance standards in the electronics industry. JEDEC was founded in 1960 and is the semiconductor engineering standardization body of the Electronic Industries Alliance (‘EIA’). EIA is a trade association that represents all areas of the electronics industry and works to promulgate standards throughout the electronics industry that meet the needs of both manufacturers and consumers.

In the area of computer memory subsystem performance standards, the JEDEC standard supports circuit topologies that include both two Dual In-Line Memory Modules (‘DIMM’) and four DIMMs. Memory subsystems implementing two DIMM topologies according to JEDEC standards may operate at speeds up to 667 megabytes per second. Memory subsystems implementing four DIMM topologies according to JEDEC standards may operate at speeds up to 400 megabytes per second. Operating memory subsystems implementing either the two DIMM topology or the four DIMM topology at higher speeds results in memory subsystem data error due to signal reflections or inter symbol interference.

### SUMMARY OF THE INVENTION

A multi-memory module circuit topology is disclosed that includes a memory controller, a plurality of memory modules connected to the memory controller through a memory bus, and a resonator connected to the plurality of memory modules in a starburst topology. A method for reducing impedance discontinuities in a multi-memory module circuit is disclosed that includes providing a plurality of memory modules connected to a memory controller through a memory bus, selecting a starburst topology, and connecting a resonator to the plurality of memory module in dependence upon the selected starburst topology. An additional method for reducing impedance discontinuities in a multi-memory module circuit is disclosed that includes providing by a resonator a predetermined discontinuity reducing impedance at a predetermined location in the multi-memory module circuit between at least two memory modules, the multi-memory module circuit having a plurality of components of logically arranged around the predetermined location.

The foregoing and other objects, features and advantages of the invention will be apparent from the following more particular descriptions of exemplary embodiments of the invention as illustrated in the accompanying drawings wherein like reference numbers generally represent like parts of exemplary embodiments of the invention.

### BRIEF DESCRIPTION OF THE DRAWINGS

FIG. 1 sets forth a line drawing illustrating an exemplary multi-memory module circuit topology according to embodiments of the present invention.

FIG. 2 sets forth a line drawing illustrating a further exemplary multi-memory module circuit topology according to embodiments of the present invention.

FIG. 3 sets forth a line drawing illustrating a further exemplary multi-memory module circuit topology according to embodiments of the present invention.

FIG. 4 sets forth a line drawing illustrating a further exemplary multi-memory module circuit topology according to embodiments of the present invention.

FIG. 5 sets forth a line drawing illustrating a further exemplary multi-memory module circuit topology according to embodiments of the present invention.

FIG. 6A sets forth an eye-diagram that illustrates waveforms of electronic signals in a circuit implementing a multi-memory module circuit topology according to the prior art.

FIG. 6B sets forth an eye-diagram that illustrates waveforms of electronic signals in a circuit implementing an exemplary multi-memory module circuit topology according to embodiments of the present invention.

FIG. 7 sets forth a flow chart illustrating an exemplary method for reducing impedance discontinuities in a multi-memory module circuit according to embodiments of the present invention

### DETAILED DESCRIPTION OF EXEMPLARY EMBODIMENTS

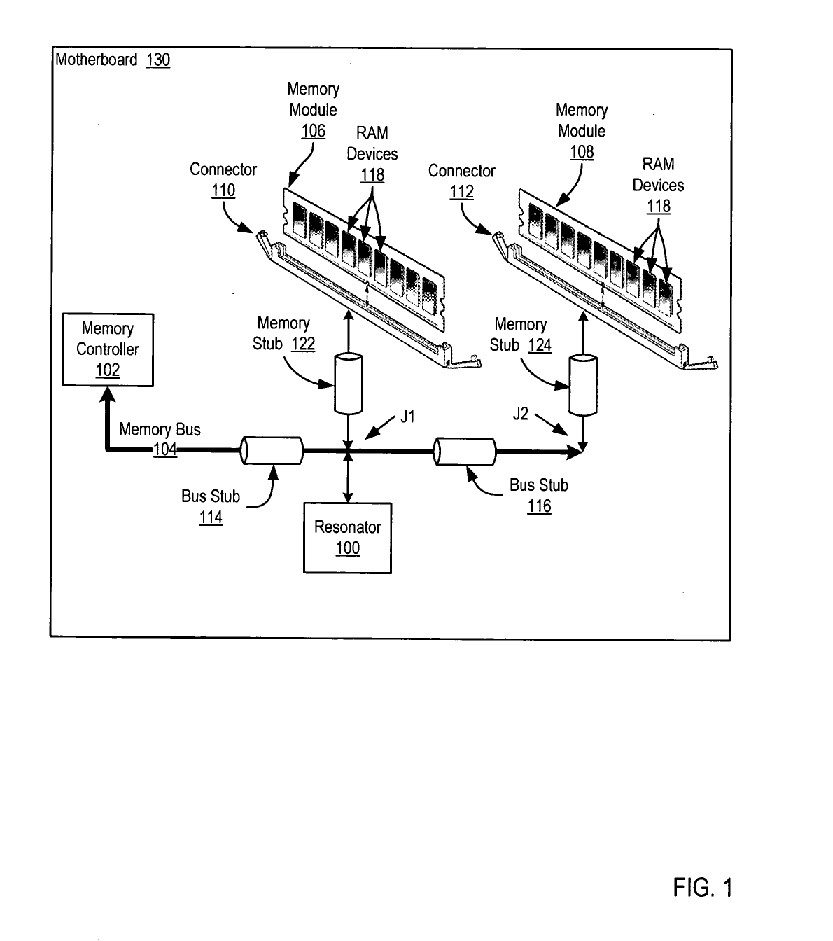

Exemplary multi-memory module circuit topologies according to embodiments of the present invention are described with reference to the accompanying drawings, beginning with FIG. 1. FIG. 1 sets forth a line drawing illustrating an exemplary multi-memory module circuit topology according to embodiments of the present invention. The exemplary multi-memory module circuit topology of FIG. 1 includes a memory controller (102), a plurality of memory modules (106, 108) connected to the memory controller (102) through a memory bus (104), and a resonator (100) connected to the plurality of memory modules (106, 108) in a starburst topology. The exemplary multi-memory module circuit topology of FIG. 1 advantageously operates to reduce impedance discontinuities in the multi-memory module circuit depicted in FIG. 1. An impedance discontinuity is a boundary between mediums having different impedances. As an electronic signal in a circuit encounters an impedance discontinuity, a portion of the electronic signal is reflected back toward the source of the signal. The reflected portion of the original signal is called a ‘signal reflection.’ The remaining portion of the original signal continues along the original path.

Signal reflections resulting from impedance discontinuities may introduce negative effects into a circuit. At each point along the circuit where an impedance discontinuity produces a signal reflection, the amplitude of the original electronic signal transmitted through the circuit is reduced. In addition, as signal reflections reflect back and forth through the circuit, the signal reflections may interfere with the original electronic signal. Such signal interference may result in the wrong voltages reaching the intended recipient of the electronic signal and therefore produce data errors.

In the exemplary circuit topology of FIG. 1, a memory controller (102) transmits and receives electronic signals from memory modules (106, 108). Memory controller (102) is computer hardware for controlling access to the random access memory (‘RAM’) devices installed on memory modules. The memory controller (102) generates the necessary signals to control the reading and writing of information from and to the RAM devices, and serves as an interface for the RAM devices with the other major parts of a computer system. When designing the memory controller (102), computer architects typically integrate the memory controller (102) into the system chipset of a motherboard. In the exemplary circuit topology of FIG. 1, the memory controller (102) is installed on motherboard (130). Examples of memory controllers useful for multi-memory module circuit topologies according to embodiments of the present invention may include the Intel® E7520 Memory Controller Hub chipset or the AMD-760™ chipset.

The motherboard (130) in the exemplary circuit topology of FIG. 1 also has installed upon it connectors (110, 112). A connector is hardware for mounting a memory module to a motherboard and electrically connecting a memory module to a memory bus. In the exemplary circuit topology of FIG. 1, memory module (106) mounts to motherboard (130) by connector (110). Memory module (108) mounts to motherboard (130) by connector (112).

In the exemplary circuit topology of FIG. 1, each memory module (106, 108) has installed upon it a number of random access memory devices (118). A memory module is a small printed circuit board or other substrate having mounted upon it a plurality of RAM devices and the supporting circuitry and components for those RAM devices. Examples of a memory module that may be improved for multi-memory module circuit topologies according to embodiments of the present invention may include single in-line memory module (‘SIMM’) or dual in-line memory module (‘DIMM’). The RAM devices (118) in the example of FIG. 1 are integrated circuit chips that store data for access in any order. Examples of RAM devices that may be useful for multi-memory module circuit topologies according to embodiments of the present invention may include static RAM (‘SRAM’), dynamic RAM (‘DRAM’), synchronous DRAM (‘SDRAM’), double data rate synchronous DRAM (‘DDR SDRAM’), and so on. In the example of FIG. 1, memory modules (106, 108) are implemented as DIMMs that include a number of DRAM memory devices.

In the exemplary circuit topology of FIG. 1, memory modules (106, 108) connect to the memory controller (102) through a memory bus (104). A memory bus is one or more bi-directional data transmission pathways that carry electronic signal information between the components connected to the memory bus. In the example of FIG. 1, memory modules connect to the memory bus through memory stubs. A stub is a portion of a data transmission pathway. A memory stub is a stub connecting a memory module to a memory bus. The point along a memory bus at which a memory stub connects a memory module to the memory bus is referred to as a ‘junction.’ In the example of FIG. 1, memory module (106) connects to the memory bus (104) through memory stub (122) at junction ‘J1,’ and memory module (108) connects to the memory bus (104) through memory stub (124) at junction ‘J2.’ Memory stub (122) begins at junction ‘J1’ on the memory bus (104) and ends on memory module (106). Memory stub (124) begins at junction ‘J2’ on the memory bus (104) and ends on the memory module (108). In the exemplary circuit topology of FIG. 1, impedance discontinuities along memory bus (104) occur at junction ‘J1’ and junction ‘J2’ because the memory stubs (122, 124) and the memory modules (106, 108) connected to the memory bus (104) at junctions ‘J1’ and ‘J2’ form capacitive loads that modify the current flow along the memory bus (104) at junctions ‘J1’ and ‘J2.’

In the exemplary circuit topology of FIG. 1, memory bus (104) includes memory bus stubs (114, 116). Memory bus stubs are portions of the one or more data transmission pathways that make up a memory bus. In the example of FIG. 1, the memory bus stubs (114, 116) are implemented as traces along the motherboard (130). In the example of FIG. 1, memory bus stub (114) begins at the memory controller (102) and ends at junction ‘J I’ where memory stub (122) connects to the memory bus (104). Memory bus stub (116) begins at junction ‘J1’ where memory stub (122) connects to the memory bus (104) and ends at junction ‘J2’ where memory stub (124) connects to the memory bus (104).

In the exemplary circuit topology of FIG. 1, the resonator (100) connects to memory modules (106, 108) in a starburst topology. The resonator (100) is an electronic component having particular impedance characteristics capable of minimizing impedance discontinuities along memory bus (104). The impedance characteristics of the resonator (104) may be static such that the impedance discontinuities along the memory bus (104) are minimized for a particular frequency band. The impedance characteristics of the resonator may also, however, be dynamic such that the impedance discontinuities along the memory bus (104) are minimized for any frequency band.

A starburst topology according to the present invention is typically implemented as a logical arrangement of components in a multi-memory module circuit topology around a particular location. A starburst topology is so-called because often the geometric arrangement of the components visually resembles a star. Some starburst topologies, however, have a logical arrangement around a particular location that is implemented in a geometric arrangement of the components that does not visually resemble a star. To implement a starburst topology according to the present invention, components of the circuit topology are logically arranged around a particular location of the multi-memory module circuit between memory modules. The particular location around which the components are arranged will vary depending on the impedances of other circuit components, the number of memory modules included in a particular circuit topology, spatial limitations of a particular geographic arrangement of a circuit topology, the number and physical location of memory bus stubs, the number and physical location of memory stubs, the physical configuration of the stubs in a particular circuit topology, and many other factors as will occur to those of skill in the art.

The exemplary starburst topology of FIG. 1 includes an arrangement of electronic circuit components in which a resonator (100) connects to the electronic circuit between memory modules. In the exemplary circuit topology of FIG. 1, the electronic circuit between memory modules (106, 108) includes memory stubs (122, 124), junctions ‘J1’ and ‘J2,’ and bus stub (116). The resonator (100) of FIG. 1 connects to the electronic circuit between memory modules (106, 108) at junction ‘J1.’ When connecting the resonator (100) to the memory modules in a starburst topology at a junction, the resonator (100) may connect to the electric circuit between the memory modules at any junction along the memory bus. To minimize impedance discontinuity, a resonator would ideally switch, instantaneously, its connection to a memory bus to the junction corresponding to the memory module transmitting or receiving electronic signals at any given time. For example, when memory module (106) receives or transmits electronic signals, the resonator (100) ideally connects to the memory bus (104) at junction ‘J1’ to minimize impedance discontinuities along the memory bus (104). Similarly, when memory module (108) receives or transmits electronic signals, the resonator (100) ideally connects to the memory bus (104) at junction ‘J2’ to minimize impedance discontinuities along the memory bus (104). Switching the connection of the resonator (100) to the memory bus (104) between junctions ‘J1’ and ‘J2,’ may, however, prove impractical at the high frequencies with which electronic signals travel along memory bus (104). For an overall average reduction in the impedance discontinuity along the memory bus (104), the resonator (100) may, therefore, connect to the memory bus (104) at the junction located in the middle of all the junctions along the memory bus (104). When an odd number of junctions exist along a memory bus, the junction in the middle of all the junctions is readily apparent. For example, when three junctions exist along the memory bus, the middle junction is the second junction. When an even number of junctions exist along a memory bus, however, two junctions serve as the junctions in the middle of all the junctions along the memory bus. For example, when four junctions exist along the memory bus, the second and third junctions serve as the middle junctions. When an even number of junctions exist along a memory bus, a resonator (100) may connect to a memory bus at the junction closest to the memory controller of the two junctions that serve as the middle junctions for an overall average reduction in the impedance discontinuity along the memory bus (104). In the example of FIG. 1, the resonator (100) connects to the memory bus (104) at junction ‘J1.’

In the exemplary circuit topology of FIG. 1, the impedance of the resonator (100) connected to the memory modules through the memory bus (104) at junction ‘J1’ is tuned to minimize the impedance discontinuities along the memory bus (104). The exemplary circuit topology of FIG. 1 advantageously reduces impedance discontinuities in a multi-memory module circuit according to embodiments of the present invention by providing by a resonator a predetermined discontinuity reducing impedance at a predetermined location in the multi-memory module circuit between at least two memory modules. The multi-memory module circuit has a plurality of components logically arranged around the predetermined location. The impedance of the resonator (100) that minimizes the impedance discontinuities along the memory bus (104) will vary according to the impedance of other components electrically connected to the resonator (100). In the example of FIG. 1, the other components electrically connected to the resonator include memory controller (102), bus stubs (114, 116), memory stubs (122, 124), and memory modules (106, 108). Because the resonator (100) operates to minimize the impedance discontinuities along the memory bus (104), the exemplary multi-memory module circuit topology advantageously reduces signal reflection along the memory bus.

In the exemplary circuit topology of FIG. 1, the resonator (100) is mounted on the motherboard (130). The resonator (100) may be mounted on the motherboard (130) by fastening the resonator (100) to the motherboard (130) using, for example, surface mounting technology or through-hole mounting technology. Surface mount technology connects electronic components to a motherboard by soldering electronic component leads or terminals to the top surface of the motherboard. Through-hole mount technology connects electronic components to an electronic circuit board by inserting component leads through holes in the motherboard and then soldering the leads in place on the opposite side of the motherboard. The resonator (100) may also be mounted on the motherboard (130) by embedding the resonator (100) into the substrate used to make the motherboard (130) using traditional printed circuit board or integrated circuit manufacturing techniques.

In the exemplary circuit topology of FIG. 1, the resonator (100) may be implemented with various electronic components. The resonator (100) may be implemented as a stub. Readers will recall from above that a stub is typically implemented as a trace along a printed circuit board or other substrate. Varying the width of the trace along the substrate may, therefore, vary the impedance of the resonator (100) for minimizing the impedance discontinuities along the memory bus (104). Implementing the resonator (100) as a stub advantageously provides a multi-memory module circuit topology that minimizes impedance discontinuities using currently available printed circuit board manufacturing methods.

In the exemplary circuit topology of FIG. 1, the resonator (100) may also be implemented as one or more connected passive components such as, for example, resistors, capacitors, inductors, and so on. Varying the values associated with such passive components may vary the impedance of the resonator (100) for minimizing the impedance discontinuities along the memory bus (104). Implementing the resonator (100) as one or more connected passive components advantageously provides a multi-memory module circuit topology that minimizes impedance discontinuity using traditional circuit components.

Although the resonator (100) in the exemplary circuit topology of FIG. 1 may be implemented as a stub or one or more connected passive components, such implementations of a resonator are for explanation and not for limitation. In fact, the resonator (100) may also be implemented using active components such as, for example, a memory module. Implementing the resonator (100) as a memory module advantageously provides a multi-memory module circuit topology that minimizes impedance discontinuity and that provides added circuit functionality.

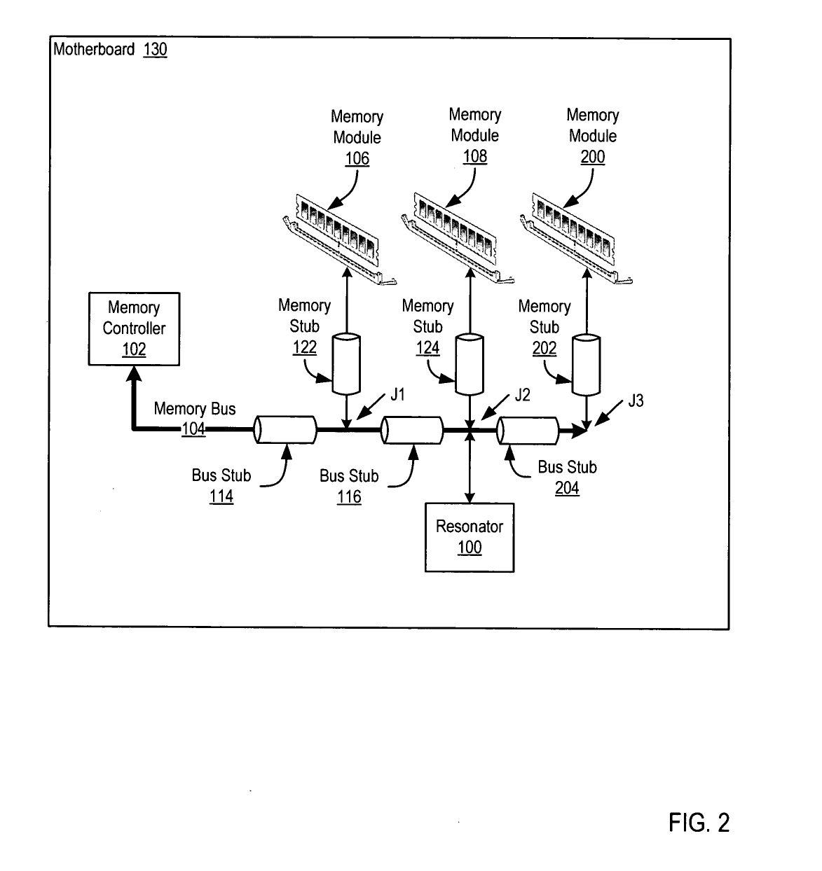

Readers will notice that the exemplary multi-memory module circuit topology depicted in FIG. 1 includes only two memory modules. Multi-memory module circuit topologies according to embodiments of the present invention may also include more than two memory modules. For further explanation, therefore, FIG. 2 sets forth a line drawing illustrating a further exemplary multi-memory module circuit topology according to embodiments of the present invention that includes three memory modules. The exemplary multi-memory module circuit topology of FIG. 2 includes a memory controller (102), a plurality of memory modules (106, 108, 200) connected to the memory controller (102) through a memory bus (104), and a resonator (100) connected to the plurality of memory modules (106, 108, 200) in a starburst topology.

The exemplary multi-memory module circuit topology of FIG. 2 is similar to the exemplary multi-memory module circuit topology of FIG. 1. That is, the example of FIG. 2 is similar to the example of FIG. 1 in that the exemplary multi-memory module circuit topology of FIG. 2 includes motherboard (130), memory controller (102), memory modules (106, 108), memory stubs (122, 124), memory bus (104), bus stubs (114, 116), junctions ‘J1’ and ‘J2,’ and resonator (100). The exemplary multi-memory module circuit topology of FIG. 2 differs from the exemplary multi-memory module circuit topology of FIG. 1 in that the exemplary multi-memory module circuit topology of FIG. 2 also includes memory module (200), memory stub (202), bus stub (204), and junction ‘J3.’

In the exemplary circuit topology of FIG. 2, the memory module (200) connects to the memory controller (102) through the memory bus (104). The memory module (200) connects to the memory bus (104) through memory stub (202). The memory stub (202) begins at the memory bus (104) and ends on the memory module (200). The point along the memory bus (104) where the memory stub (202) connects to the memory bus (104) is junction ‘J3.’

To provide additional memory bus length for connecting memory module (200) to the memory bus (104), the memory bus (104) in the example of FIG. 2 also includes memory bus stub (204). Memory bus stub (204) of FIG. 2 is implemented as a trace along the motherboard (130). Memory bus stub (204) begins at junction ‘J2’ where memory stub (124) connects to the memory bus (104) and ends at junction ‘J3’ where memory stub (202) connects to the memory bus (104). In the example of FIG. 2, impedance discontinuities along memory bus (104) occur at junctions ‘J1,’ ‘J2,’ and ‘J3’ because the memory stubs (122, 124, 202) and the memory modules (106, 108, 200) connected to the memory bus (104) at junctions ‘J1,’ ‘J2,’ and ‘J3’ form capacitive loads that modify the current flow along the memory bus (104) at junctions ‘J1,’ ‘J2,’ and ‘J3.’

A starburst topology according to the present invention is typically implemented as a logical arrangement of components in a multi-memory module circuit topology around a particular location. A starburst topology is so-called because often the geometric arrangement of the components visually resembles a star. Some starburst topologies, however, have a logical arrangement around a particular location that is implemented in a geometric arrangement of the components that does not visually resemble a star. To implement a starburst topology according to the present invention, components of the circuit topology are logically arranged around a particular location of the multi-memory module circuit between memory modules.

In the exemplary circuit topology of FIG. 2, the resonator (100) is mounted on the motherboard (130). The resonator (100) connects to memory modules (106, 108, 200) in a starburst topology. Readers will recall from above that a starburst topology is implemented as a logical arrangement of components in a multi-memory module circuit topology around a particular location of the multi-memory module circuit between memory modules. In the exemplary circuit topology of FIG. 2, the electronic circuit between memory modules (106, 108, 200) includes memory stubs (122, 124, 202), junctions ‘J1,’ ‘J2,’ and ‘J3,’ and bus stubs (116, 204). Readers will also recall from above that the resonator (100) may connect to the memory modules (106, 108, 200) in a starburst topology through memory bus (104) at the junction located in the middle of all the junctions. In the example of FIG. 2, junction ‘J2’ is the junction located in the middle of all the junctions ‘J1,’ ‘J2,’ and ‘J3.’ The resonator (100) of FIG. 2, therefore, is connected to memory modules (106, 108, 200) in a starburst topology at junction ‘J2’ for an overall average reduction in the impedance discontinuity along the memory bus (104).

In the exemplary circuit topology of FIG. 2, the impedance of the resonator (100) connected to the memory modules through the memory bus (104) at junction ‘J2’ is tuned to minimize the impedance discontinuities along the memory bus (104). The exemplary circuit topology of FIG. 2 advantageously reduces impedance discontinuities in a multi-memory module circuit according to embodiments of the present invention by providing by a resonator a predetermined discontinuity reducing impedance at a predetermined location in the multi-memory module circuit between at least two memory modules. The multi-memory module circuit has a plurality of components logically arranged around the predetermined location. As mentioned above, the impedance of the resonator (100) that minimizes the impedance discontinuities along the memory bus (104) will vary according to the impedance of other components electrically connected to the resonator (100). Reducing impedance discontinuities in a multi-memory module circuit advantageously reduces signal reflection along the memory bus (104).

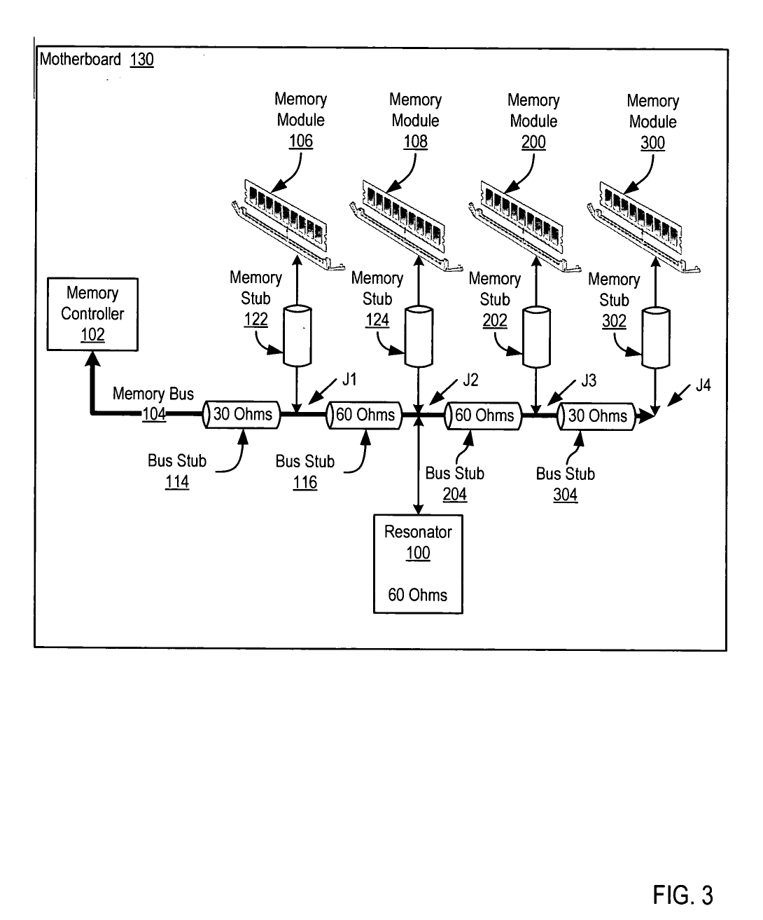

Readers will notice that the exemplary multi-memory module circuit topology depicted in FIGS. 2 and 3 include two memory modules and three memory modules, respectively. There is, however, no maximum number of memory modules that may be included in multi-memory module circuit topologies according to embodiments of the present invention. For further explanation, therefore, FIG. 3 sets forth a line drawing illustrating a further exemplary multi-memory module circuit topology according to embodiments of the present invention that includes four memory modules. The exemplary multi-memory module circuit topology of FIG. 3 includes a memory controller (102), a plurality of memory modules (106, 108, 200, 300) connected to the memory controller (102) through a memory bus (104), and a resonator (100) connected to the plurality of memory modules (106, 108, 200, 300) in a starburst topology.

The exemplary multi-memory module circuit topology of FIG. 3 is similar to the exemplary multi-memory module circuit topology of FIG. 2. That is, the example of FIG. 3 is similar to the example of FIG. 2 in that the exemplary multi-memory module circuit topology of FIG. 3 includes motherboard (130), memory controller (102), memory modules (106, 108, 200), memory stubs (122, 124, 202), memory bus (104), bus stubs (114, 116, 204), junctions ‘J1,’ ‘J2,’ and ‘J3,’ and resonator (100). The exemplary multi-memory module circuit topology of FIG. 3 differs from the exemplary multi-memory module circuit topology of FIG. 2 in that the exemplary multi-memory module circuit topology of FIG. 3 also includes memory module (300), memory stub (302), bus stub (304), and junction ‘J4.’

In the exemplary circuit topology of FIG. 3, the memory module (300) connects to the memory controller (102) through the memory bus (104). The memory module (300) connects to the memory bus (104) through memory stub (302). The memory stub (302) begins at the memory bus (104) and ends on the memory module (300). The point along the memory bus (104) where the memory stub (302) connects to the memory bus (104) is junction ‘J4.’

To provide additional memory bus length for connecting memory module (300) to the memory bus (104), the memory bus (104) in the example of FIG. 3 also includes memory bus stub (304). Memory bus stub (304) of FIG. 3 is implemented as a trace along the motherboard (130). Memory bus stub (304) begins at junction ‘J3’ where memory stub (202) connects to the memory bus (104) and ends at junction ‘J4’ where memory stub (302) connects to the memory bus (104). In the example of FIG. 1, impedance discontinuities along memory bus (104) occur at junctions ‘J1,’ ‘J2,’ ‘J3,’ and ‘J4’ because the memory stubs (122, 124, 202, 302) and the memory modules (106, 108, 200, 300) connected to the memory bus (104) at junctions ‘J1,’ ‘J2,’ ‘J3,’ and ‘J4’ form capacitive loads that modify the current flow along the memory bus (104) at junctions ‘J1,’ ‘J2,’ ‘J3,’ and ‘J4.’

In the exemplary circuit topology of FIG. 3, the resonator (100) is mounted on the motherboard (130). The resonator (100) connects to memory modules (106, 108, 200, 300) in a starburst topology. Readers will recall from above that a starburst topology is implemented as a logical arrangement of components in a multi-memory module circuit topology around a particular location of the multi-memory module circuit between memory modules. In the exemplary circuit topology of FIG. 3, the electronic circuit between memory modules (106, 108, 200, 300) includes memory stubs (122, 124,202, 302), junctions ‘J1,’ ‘J2,’ ‘J3,’ and ‘J4,’ and bus stubs (116, 204, 304). Readers will also recall from above that when a memory bus has an even number of junctions, the resonator (100) may connect to memory modules in a starburst topology through a memory bus at the junction closest to the memory controller of the two junctions that serve as the middle junctions. In the example of FIG. 3, junction ‘J2’ is the junction closet to the memory controller (104) of the two junctions ‘J2’ and ‘J3’ that serve as the middle junctions for all the junctions ‘J1,’ ‘J2,’ ‘J3,’ and ‘J4.’ The resonator (100) of FIG. 3, therefore, connects to memory modules (106, 108, 200, 300) in a starburst topology at junction ‘J2’ for an overall average reduction in the impedance discontinuity along the memory bus (104).

As mentioned above, the impedance of the resonator (100) that minimizes the impedance discontinuities along the memory bus (104) will vary according to the impedance of other components electrically connected to the resonator (100). In the example of FIG. 3, the memory bus (104) includes at least two stubs having mismatched impedances that connect to the resonator (100). Bus stubs (114, 304) have impedance values of 30 Ohms for the operational frequency of the circuit depicted in FIG. 3, while bus stubs (116, 204) have impedance values of 60 Ohms for the operational frequency of the circuit depicted in FIG. 3.

In the exemplary circuit topology of FIG. 3, the impedance of the resonator (100) connected to the memory modules through the memory bus (104) at junction ‘J2’ is tuned to minimize the impedance discontinuities along the memory bus (104). The exemplary circuit topology of FIG. 3 advantageously reduces impedance discontinuities in a multi-memory module circuit according to embodiments of the present invention by providing by a resonator a predetermined discontinuity reducing impedance at a predetermined location in the multi-memory module circuit between at least two memory modules. The multi-memory module circuit has a plurality of components logically arranged around the predetermined location. The impedance provided by the resonator (100) may be the same impedance as at least one stub and may be a mismatched impedance with at least one other stub. In the example of FIG. 3, the resonator (100) has the same impedance as bus stubs (116, 204) and has a mismatched impedance with bus stubs (114, 304). The impedance values of the components included in the exemplary multi-memory module circuit topology of FIG. 3, advantageously reduce signal reflection along the memory bus (104) by reducing the impedance discontinuities along memory bus (104).

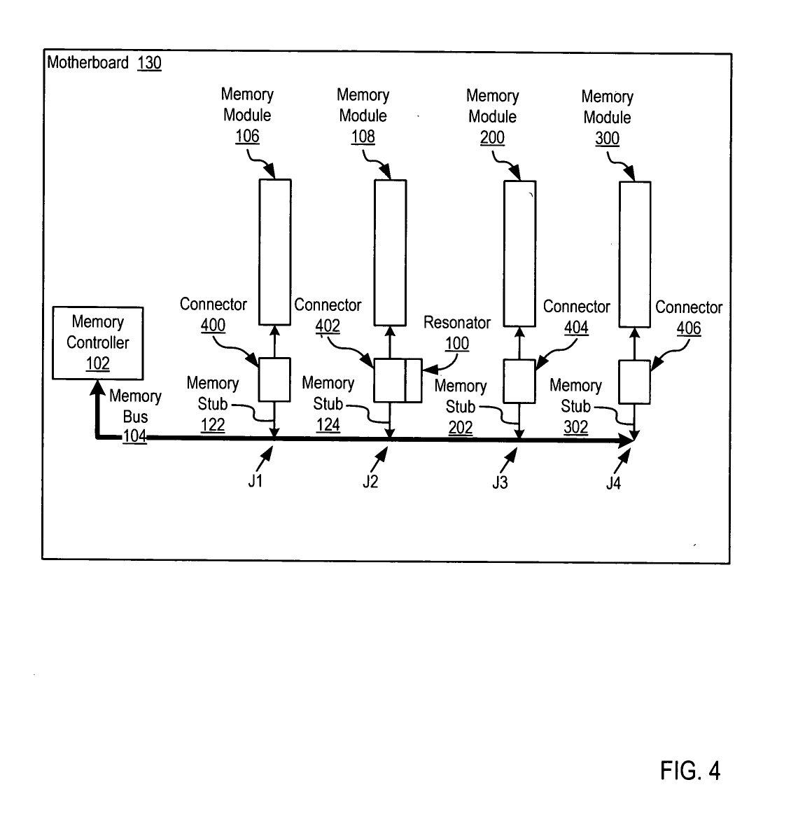

Readers will note that the resonators depicted in FIGS. 1, 2, and 3 mount on motherboards and connect to memory buses at junctions along such memory buses. A resonator that mounts on a motherboard and connects to a memory buses at a junction along the memory bus, however, is for explanation and not for limitation. The resonator may also mount on a connector for mounting a memory module to a motherboard and connect to the memory stub connecting a memory module to a memory bus. For further explanation, therefore, FIG. 4 sets forth a line drawing illustrating a further exemplary multi-memory module circuit topology according to embodiments of the present invention that includes a resonator (100) mounted on a connector (402) between a memory bus (104) and at least one memory module (108).

The exemplary multi-memory module circuit topology of FIG. 4 includes a memory controller (102), a plurality of memory modules (106, 108, 200, 300) connected to the memory controller (102) through a memory bus (104), and a resonator (100) connected to the plurality of memory modules (106, 108, 200, 300) in a starburst topology. The exemplary multi-memory module circuit topology of FIG. 4 is similar to the exemplary multi-memory module circuit topology of FIG. 3. That is, the example of FIG. 4 is similar to the example of FIG. 3 in that the exemplary multi-memory module circuit topology of FIG. 4 includes motherboard (130), memory controller (102), memory modules (106, 108, 200, 300), memory stubs (122, 124, 202, 302), memory bus (104), junctions ‘J1,’ ‘J2,’ ‘J3,’ and ‘J4,’ and resonator (100).

The exemplary multi-memory module circuit topology of FIG. 4 differs from the exemplary multi-memory module circuit topology of FIG. 3 in that the exemplary multi-memory module circuit topology of FIG. 4 also includes connectors (400, 402, 404, 406). As mentioned above, connectors are hardware installed on a motherboard for mounting memory modules to a motherboard. In the example of FIG. 4, connector (400) mounts memory module (106) to the motherboard (130). Connector (402) mounts memory module (108) to the motherboard (130). Connector (404) mounts memory module (200) to the motherboard (130). Connector (406) mounts memory module (300) to the motherboard (130).

In the exemplary multi-memory module circuit topology of FIG. 4, the resonator (100) is mounted on connector (402) between the memory bus (104) and the memory module (108). The resonator (100) may mount on the connector (402) by fastening the resonator (100) to the connector (402). The resonator (100) may also mount on the connector (402) by embedding the resonator (100) into the connector (402).

The resonator (100) connects to memory modules (106, 108, 200, 300) in a starburst topology. Readers will recall from above that a starburst topology is implemented as a logical arrangement of components in a multi-memory module circuit topology around a particular location of the multi-memory module circuit between memory modules. In the example of FIG. 4, the electronic circuit between memory modules (106, 108, 200, 300) includes memory stubs (122, 124, 202, 302), junctions ‘J1,’ ‘J2,’ ‘J3,’ and ‘J4,’ and the memory bus (104) between junctions ‘J1,’ and ‘J4.’ The resonator (100) of FIG. 4 connects to memory modules through memory stub (124) connecting memory module (108) to the memory bus (104). The impedance of the resonator (100) in the exemplary circuit topology of FIG. 4 is tuned to minimize the impedance discontinuities along the memory bus (104). As mentioned above, the impedance of the resonator (100) that minimizes the impedance discontinuities along the memory bus (104) will vary according to the impedance of other components electrically connected to the resonator (100).

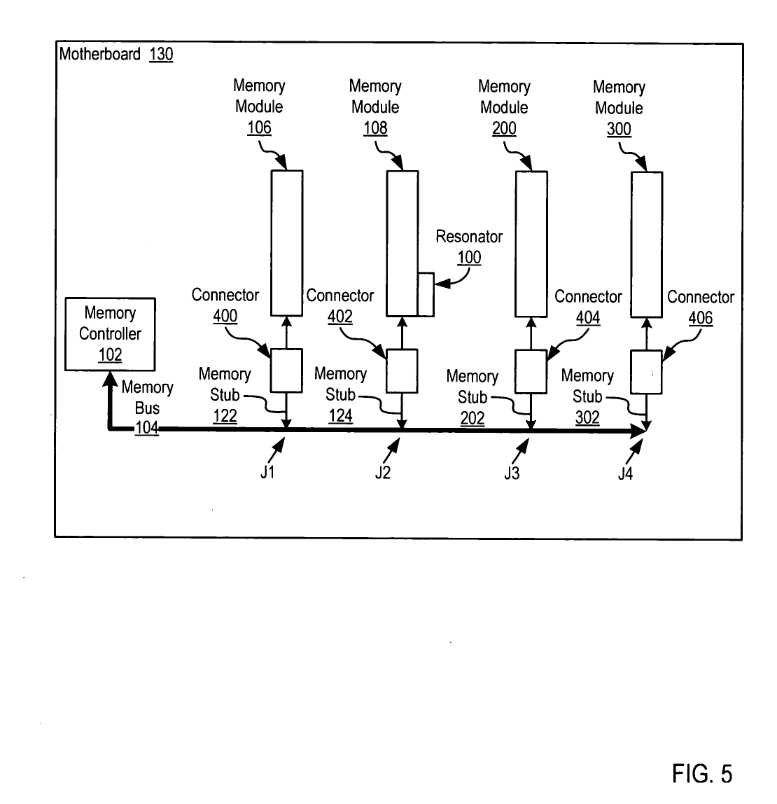

The exemplary multi-memory module circuit topology depicted FIG. 4 includes a resonator mounted on a connector between a memory bus and at least one memory module. The resonator, however, may also be mounted on a memory module. For further explanation, therefore, FIG. 5 sets forth a line drawing illustrating a further exemplary multi-memory module circuit topology according to embodiments of the present invention that includes a resonator (100) mounted on a memory module (108). A resonator (100) that mounts on memory module (108) advantageously provides a multi-memory module circuit topology according to embodiments of the present invention that does not require the alteration of existing motherboard architectures.

The exemplary multi-memory module circuit topology of FIG. 5 includes a memory controller (102), a plurality of memory modules (106, 108, 200, 300) connected to the memory controller (102) through a memory bus (104), and a resonator (100) connected to the plurality of memory modules (106, 108, 200, 300) in a starburst topology. The exemplary multi-memory module circuit topology of FIG. 5 is similar to the exemplary multi-memory module circuit topology of FIG. 4. That is, the example of FIG. 5 is similar to the example of FIG. 4 in that the exemplary multi-memory module circuit topology of FIG. 5 includes motherboard (130), memory controller (102), memory modules (106, 108, 200, 300), memory stubs (122, 124, 202, 302), connectors (400, 402, 404, 406), memory bus (104), junctions ‘J1,’ ‘J2,’ ‘J3,’ and ‘J4,’ and resonator (100).

The exemplary multi-memory module circuit topology of FIG. 5 differs from the exemplary multi-memory module circuit topology of FIG. 4 in that the exemplary multi-memory module circuit topology of FIG. 5 includes the resonator (100) mounted on memory module (108). The resonator (100) may mount on the memory module (108) by fastening the resonator (100) to the memory module (108) board using, for example, surface mounting technology or through-hole mounting technology. The resonator (100) may also mount on the memory module (108) by embedding the resonator (100) into the substrate used to make the memory module (108) using traditional printed circuit board or integrated circuit manufacturing techniques.

In the example of FIG. 5, the resonator (100) connects to memory modules (106, 108, 200, 300) in a starburst topology. Readers will recall from above that a starburst topology is implemented as a logical arrangement of components in a multi-memory module circuit topology around a particular location of the multi-memory module circuit between memory modules. In the example of FIG. 5, the electronic circuit between memory modules (106, 108, 200, 300) includes memory stubs (122, 124, 202, 302), junctions ‘J1,’ ‘J2,’ ‘J3,’ and ‘J4,’ and the memory bus (104) between junctions ‘J1’ and ‘J4.’ The resonator (100) of FIG. 5 connects to memory modules through memory stub (124) connecting memory module (108) to the memory bus (104). The impedance of the resonator (100) is tuned to minimize the impedance discontinuities along the memory bus (104). As mentioned above, the impedance of the resonator (100) that minimizes the impedance discontinuities along the memory bus (104) will vary according to the impedance of other components electrically connected to the resonator (100).

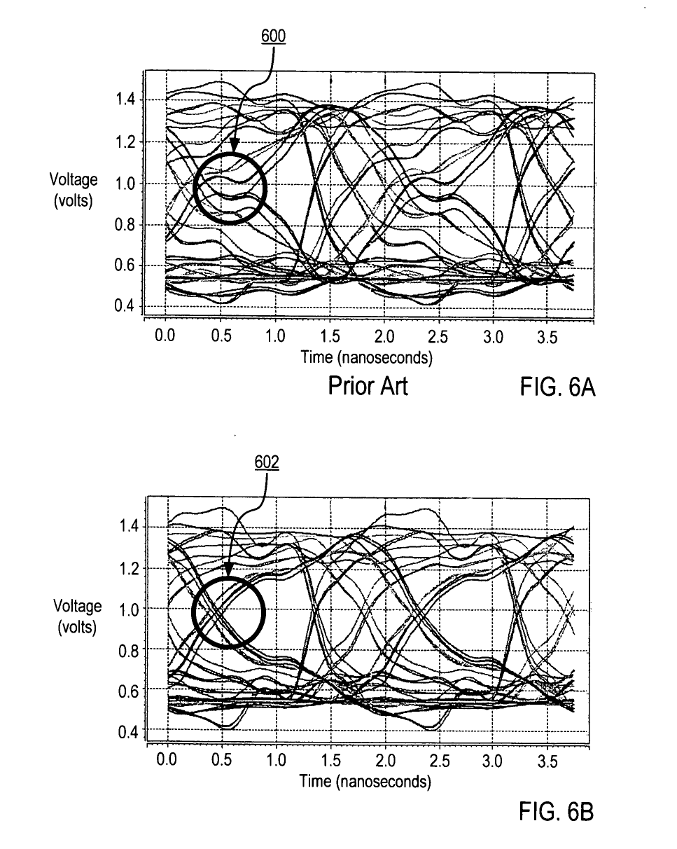

Readers will recall that the exemplary multi-memory module circuit topologies of FIGS. 1, 2, 3, 4, and 5 operate to minimize impedance discontinuities in the respective multi-memory module circuits. Minimizing the impedance discontinuities in a multi-memory module circuit advantageously reduces signal reflection in the circuit. The effects of signal reflection are typically illustrated using eye-diagrams. For further explanation, therefore, FIGS. 6A sets forth an eye-diagram that illustrates waveforms of electronic signals in a circuit implementing a multi-memory module circuit topology according to the prior art. The waveforms illustrated in FIG. 6A result from a memory controller loading data onto the memory module farthest from the memory controller in a four-DIMM circuit topology according to the prior art.

Readers will notice the effects of signal reflections in the circuit implementing a multi-memory module circuit topology according to the prior art at region (600) of FIG. 6A. The signal reflections interfere with the original signal and reduce the voltage level of the signal as shown by the ‘knee’ at region (600) of FIG. 6A. The signal interference shown at region (600) of FIG. 6A, therefore affects the propagation delay for the original signal. The propagation delay is the time delay that occurs between the time when a transmitter sends the initial wave front of an electronic signal and the time when the voltage of the electronic signal reaches a logic threshold at a receiver. The ‘knee’ at region (600) of FIG. 6A extends the propagation delay for an electronic signal and limits the effective operating frequency of the circuit implementing a multi-memory module circuit topology according to the prior art.

Turning now to FIG. 6B, FIG. 6B sets forth an eye-diagram that illustrates waveforms of electronic signals in a circuit implementing an exemplary multi-memory module circuit topology according to embodiments of the present invention. The circuit that produced the waveforms illustrated in FIG. 6B is a conventional circuit. The circuit that produced the waveforms illustrated in FIG. 6B, however, implements a circuit topology improved according to embodiments of the present invention. The waveforms illustrated in FIG. 6B result from a memory controller loading data onto the memory module farthest from the memory controller in a four-DIMM circuit topology according to embodiments of the present invention.

Readers will notice the reduced effects of signal reflections as shown at region (602) of FIG. 6B by the reduction or elimination of the ‘knee’ depicted at region (600) of FIG. 6A. The reduced effects of signal reflections decrease the propagation delay of an electronic signal in a circuit implementing an exemplary multi-memory module circuit topology according to embodiments of the present invention compared to the propagation delay of an electronic signal in a circuit implementing a multi-memory module circuit topology according to prior art. These reduced propagation delays allow circuits implementing an exemplary multi-memory module circuit topology according to embodiments of the present invention to operate at higher frequencies when compared to circuits implementing an exemplary multi-memory module circuit topology according to the prior art without an increase in data errors.

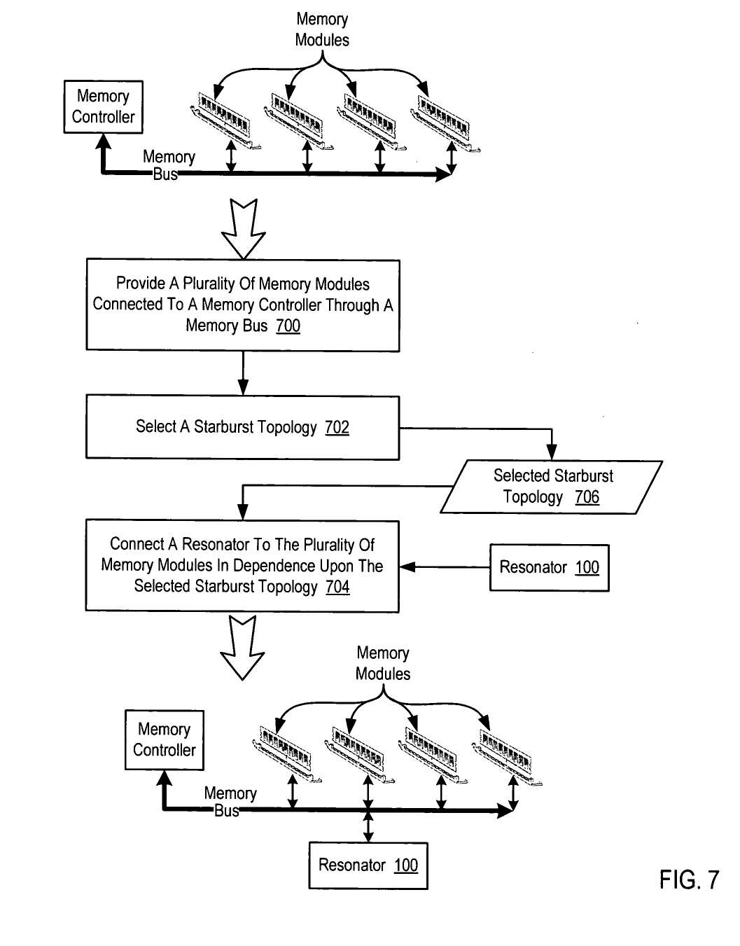

As discussed above, multi-memory module circuit topologies according to the present invention reduce impedance discontinuities in a multi-memory module circuit by providing by a resonator a predetermined discontinuity reducing impedance at a predetermined location in the multi-memory module circuit between at least two memory modules. The multi-memory module circuit in multi-memory module circuit topologies according to the present invention has a plurality of components logically arranged around the predetermined location. For further explanation, therefore, FIG. 7 sets forth a flow chart illustrating an exemplary method for reducing impedance discontinuities in a multi-memory module circuit according to embodiments of the present invention results in a multi-memory circuit topology according to embodiments of the present invention. The method of FIG. 7 includes providing (700) a plurality of memory modules connected to a memory controller through a memory bus.

The method of FIG. 7 also includes selecting (702) a starburst topology. Selecting (702) a starburst topology according to the method of FIG. 7 may be carried out by selecting a location in a multi-memory module circuit topology between at least two memory modules which results in a logical arrangement of a plurality of circuit components around the location once a resonator is connected to the multi-memory module circuit. The location is selected in dependence upon the impedances of other circuit components, the number of memory modules included in a particular circuit topology, spatial limitations of a particular geographic arrangement of a circuit topology, the number and physical location of memory bus stubs, the number and physical location of memory stubs, the physical configuration of the stubs in a particular circuit topology, and any other factors as will occur to those of skill in the art. Often, a starburst topology results in a geometric arrangement of the components in a multi-memory module circuit that visually resembles a star. Some starburst topologies, however, have a logical arrangement around a particular location that is implemented in a geometric arrangement of the components that does not visually resemble a star.

The method of FIG. 7 also includes connecting (704) a resonator (100) to the plurality of memory module in dependence upon the selected starburst topology (706). Connecting (704) a resonator to the plurality of memory modules in dependence upon the selected starburst topology (706) according to the method of FIG. 7 may be carried out by connecting (704) the resonator (100) to a location in a multi-memory module circuit topology between at least two memory modules which results in a logical arrangement of a plurality of circuit components around the location. The location at which the resonator (100) is connected to the plurality of memory modules may reside on a motherboard, in the multi-memory module circuit between a memory bus and at least one memory module, on a memory module, or any other location as will occur to those of skill in the art.

It will be understood from the foregoing description that modifications and changes may be made in various embodiments of the present invention without departing from its true spirit. The descriptions in this specification are for purposes of illustration only and are not to be construed in a limiting sense. The scope of the present invention is limited only by the language of the following claims.

What is claimed is:

1. A multi-memory module circuit topology comprising:
a memory controller;
a plurality of memory modules connected to the memory controller through a memory bus; and
a resonator connected to the plurality of memory modules in a starburst topology.

2. The circuit topology of claim 1 wherein the memory bus includes at least two stubs having mismatched impedances.

3. The circuit topology of claim 2 wherein the resonator has the same impedance as at least one stub and has a mismatched impedance with at least one other stub.

4. The circuit topology of claim 1 wherein the resonator is a stub.

5. The circuit topology of claim 1 wherein the resonator is one or more connected passive components.

6. The circuit topology of claim 1 wherein the resonator is a memory module.

7. The circuit topology of claim 1 wherein the resonator is mounted on a motherboard.

8. The circuit topology of claim 1 wherein the resonator is mounted on a connector between the memory bus and at least one memory module.

9. The circuit topology of claim 1 wherein the resonator is mounted on a memory module.

10. The circuit topology of claim 1 wherein the plurality of memory modules are a plurality of dual in-line memory modules.

11. A method for reducing impedance discontinuities in a multi-memory module circuit, the method comprising:
providing a plurality of memory modules connected to a memory controller through a memory bus;
selecting a starburst topology; and
connecting a resonator to the plurality of memory modules in dependence upon the selected starburst topology.

12. The method of claim 11 wherein the memory bus includes at least two stubs having mismatched impedances.

13. The method of claim 12 wherein the resonator has the same impedance of at least one stub and has a mismatched impedance with at least one other stub.

14. The method of claim 11 wherein the resonator is a stub.

15. The method of claim 11 wherein the resonator is one or more connected passive components.

16. The method of claim 11 wherein the resonator is a memory module.

17. A method for reducing impedance discontinuities in a multi-memory module circuit, the method comprising:
providing by a resonator a predetermined discontinuity reducing impedance at a predetermined location in the multi-memory module circuit between at least two memory modules; and
wherein a plurality of components of the multi-memory module circuit are logically arranged around the predetermined location.

18. The method of claim 17 wherein the predetermined location resides on a motherboard.

19. The method of claim 17 wherein the predetermined location resides in the multi-memory module circuit between a memory bus and at least one memory module.

20. The method of claim 17 wherein the predetermined location resides on a memory module.
